(19) United States
(12) Patent Application Publication
(10) Pub. No.: US 2024/0421058 A1
(43) Pub. Date: Dec. 19, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Minkyu KIM, Suwon-si (KR); Dahee KIM, Suwon-si (KR); Khaile KIM, Suwon-si (KR); Kyuil HWANG, Suwon-si (KR)

(73) Assignee: Samsung Electronics Co., Ltd., Suwon-si (KR)

(21) Appl. No.: 18/644,867

(22) Filed: Apr. 24, 2024

(30) Foreign Application Priority Data
Jun. 15, 2023 (KR) 10-2023-0077064

(51) Int. Cl. H01L 23/498; H01L 21/48; H01L 23/00; H01L 23/538

(52) U.S. Cl. CPC H01L 23/49822; H01L 21/4857; H01L 23/49816; H01L 23/5385; H01L 23/5389; H01L 24/08; H01L 2224/08225

(57) ABSTRACT

A semiconductor package may include a package structure on a redistribution structure. The redistribution structure may include a wiring structure and an insulating structure covering the wiring structure. The package structure may include a semiconductor chip connected to the wiring structure. The insulating structure of the redistribution structure may include a plurality of first insulating layers and a second insulating layer between the plurality of first insulating layers. The plurality of first insulating layers may include at least one of a first conductive line pattern and a first conductive via pattern. The second insulating layer may include a second conductive line pattern overlapping the first conductive line pattern in a vertical direction.

### CROSS-REFERENCE TO RELATED APPLICATION

This application is based on and claims priority under 35 U.S.C. § 119 to Korean Patent Application No. 10-2023-0077064, filed on Jun. 15, 2023 in the Korean Intellectual Property Office, the disclosure of which is incorporated by reference herein in its entirety.

### BACKGROUND

Inventive concepts relate to a semiconductor package and/or a method of manufacturing the same, and more particularly, to a semiconductor package including a redistribution structure and/or a method of manufacturing the semiconductor package.

Due to the development of electronic technology, electronic devices have become smaller, more multifunctional, and larger in capacity. Accordingly, a semiconductor package including a redistribution structure has been developed to implement a highly integrated semiconductor chip with an increased number of data input/output (I/O) connection terminals. As the line widths of wiring lines included in the redistribution structure have diversified and the minimum line width of the wiring lines has decreased, it may be necessary to develop a technique for securing the reliability of wiring lines included in the redistribution structure and having various line widths.

### SUMMARY

Inventive concepts provide a semiconductor package including a redistribution structure having a thick conductive line pattern.

Inventive concepts provide a method of manufacturing a semiconductor package including a redistribution structure having a thick conductive line pattern.

According to an embodiment of inventive concepts, a semiconductor package may include a redistribution structure including a wiring structure and an insulating structure covering the wiring structure; and a package structure on the redistribution structure, the package structure including a semiconductor chip connected to the wiring structure. The insulating structure of the redistribution structure may include a plurality of first insulating layers and a second insulating layer between the plurality of first insulating layers. The plurality of first insulating layers may include at least one of a first conductive line pattern and a first conductive via pattern. The second insulating layer may include a second conductive line pattern overlapping the first conductive line pattern in a vertical direction.

According to an embodiment of inventive concepts, a semiconductor package may include a package structure including a semiconductor chip; a first redistribution structure facing a first surface of the package structure in a vertical direction, the first redistribution structure including a first wiring structure and a first insulating structure covering the first wiring structure; and a second redistribution structure facing a second surface of the package structure in the vertical direction, the second redistribution structure including a second wiring structure and a second insulating structure covering the second wiring structure, the second surface of the package structure being opposite to the first surface of the package structure. The first insulating structure may include a plurality of first insulating layers and a second insulating layer between the plurality of first insulating layers. The plurality of first insulating layers may include at least one of a first conductive line pattern and a first conductive via pattern. The second insulating layer may include a second conductive line pattern overlapping the first conductive line pattern in the vertical direction. The second insulating structure may include a plurality of third insulating layers and a fourth insulating layer between the plurality of third insulating layers. The plurality of third insulating layers may include at least one of a third conductive line pattern and a third conductive via pattern. The fourth insulating layer may include a fourth conductive line pattern overlapping the third conductive line pattern in the vertical direction.

According to an embodiment of inventive concepts, a method of manufacturing a semiconductor package may include forming a package structure including a semiconductor chip; and forming a redistribution structure on the package structure. The forming the redistribution structure may include: forming a first conductive via pattern and a first insulating layer on the package structure, the first insulating layer covering the first conductive via pattern; forming a second conductive line pattern, a second conductive via pattern, and a second insulating layer on the first insulating layer, the second insulating layer covering the second conductive line pattern and the second conductive via pattern; and forming a first conductive line pattern and a third insulating layer on the second insulating layer, the third insulating layer covering the first conductive line pattern, the first conductive line pattern facing the second conductive line pattern in a vertical direction.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2 is an enlarged cross-sectional view of region EX1 of FIG. 1;

FIG. 3 is a cross-sectional view illustrating a semiconductor package according to another embodiment;

FIG. 4 is an enlarged cross-sectional view of region EX2 of FIG. 3;

FIG. 5 is a cross-sectional view illustrating a semiconductor package according to another embodiment; and

FIGS. 6 to 13 are cross-sectional views sequentially shown according to a manufacturing sequence to explain a method of manufacturing a semiconductor package, according to an embodiment.

### DETAILED DESCRIPTION

As used herein, the singular forms “a,” “an” and “the” are intended to include the plural forms as well, unless the context clearly indicates otherwise. The singular form of a constituent element may include a plurality of the constituent elements unless the context clearly indicates otherwise.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments of inventive concepts are described in detail with reference to the accompanying drawings. The same reference numerals are used for the same components in the drawings, and repeated descriptions thereof are omitted.

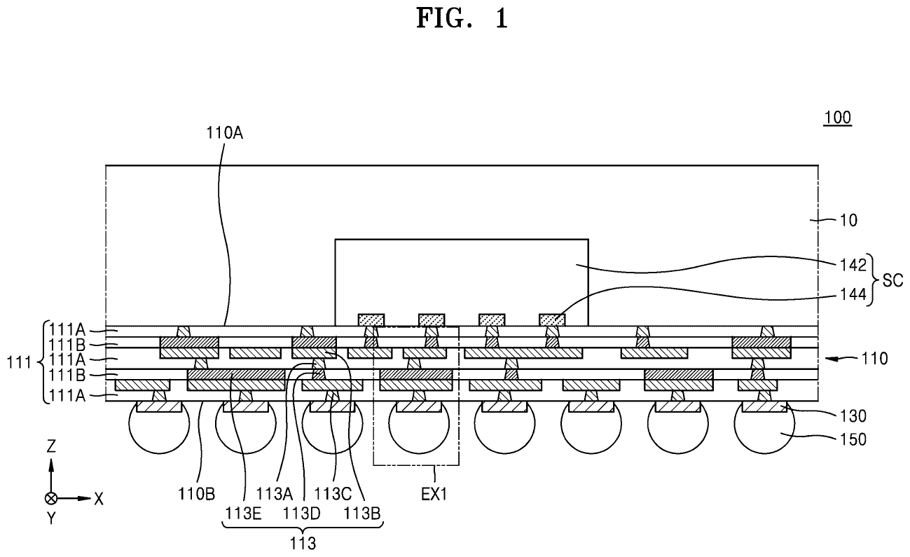

FIG. 1 is a cross-sectional view illustrating a semiconductor package 100 according to an embodiment.

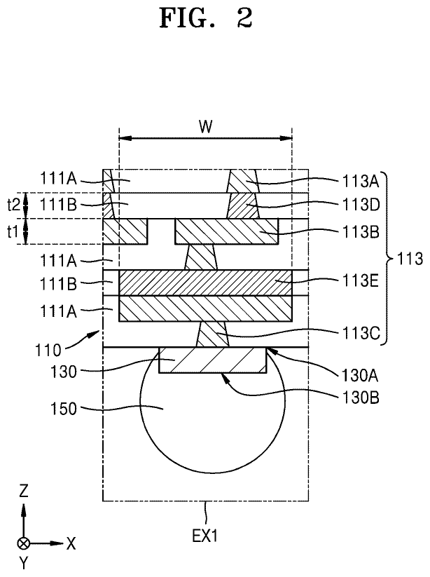

FIG. 2 is an enlarged cross-sectional view of region EX1 of FIG. 1.

Referring to FIGS. 1 and 2, the semiconductor package 100 according to an embodiment may include a package structure 10 and a redistribution structure 110.

The redistribution structure 110 may include a first surface 110A and a second surface 110B opposite to each other. The package structure 10 may include a semiconductor chip SC arranged on the first surface 110A of the redistribution structure 110.

The redistribution structure 110 may include a plurality of insulating structures 111 and a plurality of wiring structures 113. The plurality of insulating structures 111 may cover the plurality of wiring structures 113.

The plurality of wiring structures 113 may include a plurality of first conductive via patterns 113A, a plurality of first conductive line patterns 113B, a plurality of outermost wiring patterns 113C, a plurality of second conductive via patterns 113D, and a plurality of second conductive line patterns 113E. Each of inner surfaces 130A of a plurality of conductive pads 130 may be in contact with one outermost wiring pattern 113C selected from among the plurality of outermost wiring patterns 113C.

Herein, each of the plurality of first conductive via patterns 113A, the plurality of first conductive line patterns 113B, the plurality of outermost wiring patterns 113C, the plurality of second conductive via patterns 113D, and the plurality of second conductive line patterns 113E may be referred to as the wiring structure 113. Portions of the plurality of first conductive via patterns 113A, the plurality of first conductive line patterns 113B, the plurality of outermost wiring patterns 113C, the plurality of second conductive via patterns 113D, and the plurality of second conductive line patterns 113E may be connected to each other in a vertical direction (Z direction). Other portions of the plurality of first conductive via patterns 113A, the plurality of first conductive line patterns 113B, the plurality of outermost wiring patterns 113C, the plurality of second conductive via patterns 113D, and the plurality of second conductive line patterns 113E may be insulated from each other by the insulating structure 111.

In embodiments, the plurality of wiring structures 113 included in the redistribution structure 110 may include copper (Cu), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof. In particular, the second conductive line pattern 113E may include Cu, but is not limited thereto.

According to an embodiment, the insulating structure 111 may include a plurality of first insulating layers 111A and a plurality of second insulating layers 111B. The plurality of first insulating layers 111A and the plurality of second insulating layers 111B may be sequentially stacked from the first surface 110A of the redistribution structure 110. FIG. 1 illustrates that three first insulating layers 111A and two second insulating layers 111B are sequentially stacked. However, the configurations of the plurality of wiring structures 113 and the plurality of insulating structures 111 included in the redistribution structure 110 are not limited to the illustration of FIG. 1, and various modifications and changes may be made thereto.

The insulating structure 111 may include a photoimageable dielectric (PID). In embodiments, the insulating structure 111 included in the redistribution structure 110 may include at least one polymer. For example, the insulating structure 111 may include photosensitive polyimide, polybenzoxazole, polyphenol, a benzocyclobutene-based polymer, or a combination thereof. The insulating structure 111 may further include a photoactive compound. The photoactive compound may include diazonaphtoquinone (DNQ) or the like, but is not limited thereto.

The first insulating layer 111A may cover at least one of the plurality of first conductive via patterns 113A, the plurality of first conductive line patterns 113B, and the plurality of outermost wiring patterns 113C. The first insulating layer 111A that is closest to the package structure 10 in the vertical direction (Z direction) may cover the plurality of first conductive via patterns 113A.

The second insulating layer 111B may be formed between the plurality of first insulating layers 111A. The second insulating layer 111B may cover the plurality of second conductive via patterns 113D and the plurality of second conductive line patterns 113E. In this case, the thicknesses in the vertical direction (Z direction) of the plurality of second conductive via patterns 113D and the plurality of second conductive line patterns 113E may be identical to the thickness in the vertical direction (Z direction) of the second insulating layer 111B. For example, the thickness in the vertical direction (Z direction) of the second insulating layer 111B may be in a range of about 2 μm to about 5 μm.

The plurality of second conductive line patterns 113E and the plurality of first conductive line patterns 113B may overlap each other in the vertical direction (Z direction). The widths in a horizontal direction (X and Y directions in FIG. 1) of the plurality of second conductive line patterns 113E and the plurality of first conductive line patterns 113B may be identical to each other. For example, widths W in the X direction of the second conductive line pattern 113E and the first conductive line pattern 113B may be identical to each other.

A thickness t₁ in the vertical direction (Z direction) of the first conductive line pattern 113B and a thickness t₂ in the vertical direction (Z direction) of the second conductive line pattern 113E may be identical to each other, but are not limited thereto. The thickness t₁ in the vertical direction (Z direction) of the first conductive line pattern 113B may be greater than the thickness t₂ in the vertical direction (Z direction) of the second conductive line pattern 113E, and the thickness t₂ in the vertical direction (Z direction) of the second conductive line pattern 113E may be greater than the thickness t₁ in the vertical direction (Z direction) of the first conductive line pattern 113B. For example, the thickness t₁ in the vertical direction (Z direction) of the first conductive line pattern 113B may be selected from a range of about 1 μm to about 3 μm. In addition, the thickness t₂ in the vertical direction (Z direction) of the second conductive line pattern 113E may be selected from a range of about 2 μm to about 5 μm.

The second insulating layer 111B may be formed between the plurality of first insulating layers 111A, and the plurality of second conductive line patterns 113E and the plurality of first conductive line patterns 113B may face each other in the vertical direction (Z direction). Between the first conductive line patterns 113B located at different vertical levels, a plurality of insulating layers, that is, the first and second insulating layers 111A and 111B, may be formed in the vertical direction (Z direction). Herein, it is illustrated that the first insulating layer 111A and the second insulating layer 111B are formed between the first conductive line patterns 113B in the vertical direction (Z direction). However, embodiments are not limited thereto, and three or more insulating layers may be formed.

The plurality of second conductive via patterns 113D may be connected to at least one of the plurality of first conductive line patterns 113B and the plurality of first conductive via patterns 113A. The plurality of second conductive via patterns 113D may be located at the same vertical level as the plurality of second conductive line patterns 113E in the second insulating layer 111B.

As the plurality of second conductive line patterns 113E and the plurality of first conductive line patterns 113B overlap each other in the vertical direction (Z direction), the wiring structure 113 of the semiconductor package 100 of inventive concepts may have a thick conductive line pattern.

As the second conductive line pattern 113E and the first conductive line pattern 113B overlap each other in the vertical direction (Z direction), the thickness of a conductive line pattern may increase, and thus, the signal integrity (SI) and power integrity (PI) characteristics of the semiconductor package 100 may be improved.

The semiconductor chip SC may include a semiconductor device 142 and a plurality of chip pads 144 arranged on one surface of the semiconductor device 142. The semiconductor chip SC may be attached on the redistribution structure 110 such that the plurality of chip pads 144 face the redistribution structure 110. The plurality of chip pads 144 included in the semiconductor chip SC may be connected to at least one wiring structure 113.

Each of the plurality of conductive pads 130 may be connected to the outermost wiring pattern 113C adjacent to the second surface 110B of the redistribution structure 110. Each of the plurality of conductive pads 130 may include an inner surface 130A in contact with the outermost wiring pattern 113C adjacent to the second surface 110B of the redistribution structure 110, and an outer surface 130B opposite to the inner surface 130A.

Each of the plurality of conductive pads 130 may include a metal, such as Cu, Al, W, Ti, Ta, In, Mo, Mn, Co, Sn, Ni, Mg, Re, Be, Ga, or Ru, or an alloy thereof, but is not limited thereto. In embodiments, each of the plurality of conductive pads 130 may include a single metal material. In other embodiments, each of the plurality of conductive pads 130 may have a multi-layer structure in which layers include different metal materials.

A plurality of external connection terminals 150 may be arranged on the plurality of conductive pads 130 on the second surface 110B of the redistribution structure 110. Each of the plurality of external connection terminals 150 may be in contact with the outer surface 130B of one conductive pad 130 selected from among the plurality of conductive pads 130. In embodiments, each of the plurality of external connection terminals 150 may include Sn, silver (Ag), Cu, Ni, or a combination thereof, but is not limited thereto. In embodiments, each of the plurality of external connection terminals 150 may include a solder ball, but is not limited thereto.

The semiconductor chip SC included in the package structure 10 illustrated in FIG. 1 may include a semiconductor substrate. The semiconductor substrate may include a semiconductor element, such as Si or Ge, or a compound semiconductor, such as silicon carbide (SiC), gallium arsenide (GaAs), indium arsenide (InAs), or indium phosphide (InP). The semiconductor chip SC may include an active surface and an inactive surface opposite to the active surface. In embodiments, the active surface of the semiconductor chip SC may face the redistribution structure 110. The semiconductor chip SC may include a plurality of individual devices of various types.

The semiconductor chip SC may be configured to, through the chip pad 144, the redistribution structure 110, and the conductive pad 130, receive at least one of a control signal, a power signal, and a ground signal for the operation of the semiconductor chip SC, receive a data signal to be stored in the semiconductor chip SC from the outside, or provide data stored in the semiconductor chip SC to the outside.

In embodiments, the semiconductor chip SC may be a logic chip or a memory chip. The logic chip may be a microprocessor. For example, the logic chip may be a central processing unit (CPU), a controller, an application-specific integrated circuit (ASIC), or the like. The memory chip may be a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). In embodiments, the memory chip may be a high bandwidth memory (HBM) DRAM semiconductor chip.

In other embodiments, the semiconductor chip SC may be a system-on-chip (SoC)-type application processor (AP) chip used in a mobile system, for example, a mobile phone, an MP3 player, a navigation device, a portable multimedia player (PMP), or the like, or a double data rate (DDR) synchronous dynamic random access memory (SDRAM) chip (hereinafter, referred to as a “DDR chip”) used in a mobile system.

According to the semiconductor package 100 described with reference to FIGS. 1 and 2, as the second conductive line pattern 113E and the first conductive line pattern 113B included in the redistribution structure 110 overlap each other in the vertical direction (Z direction), the thickness of a conductive line pattern may increase, and thus, the SI and PI characteristics of the semiconductor package 100 may be improved. Accordingly, the reliability of the semiconductor package 100 may be improved.

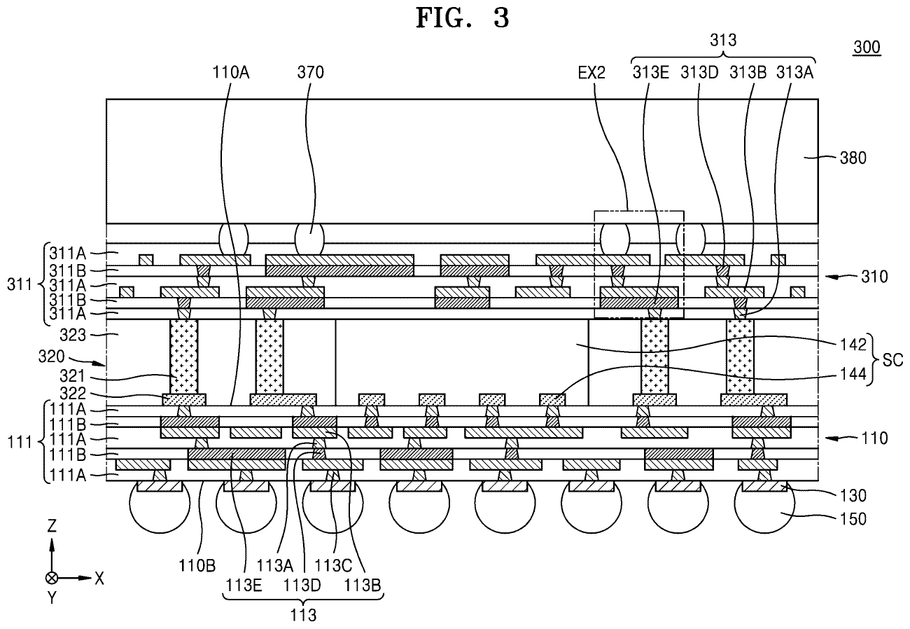

FIG. 3 is a cross-sectional view illustrating a semiconductor package 300 according to another embodiment.

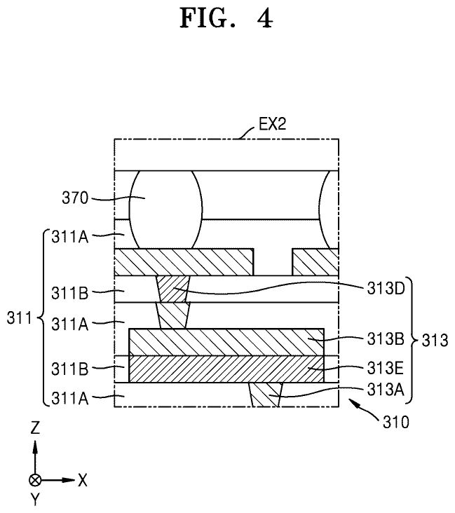

FIG. 4 is an enlarged cross-sectional view of region EX2 of FIG. 3. In FIGS. 3 and 4, the same reference numerals as those in FIGS. 1 and 2 denote the same members, and detailed descriptions thereof are omitted.

Referring to FIG. 3, the semiconductor package 300 may include a first package structure 320 arranged on the redistribution structure 110. The first package structure 320 may be a semiconductor package having a fan-out wafer-level package (FOWLP) structure. The first package structure 320 may have substantially the same configuration as that of the package structure 10 described with reference to FIGS. 1 and 2.

However, the first package structure 320 may further include a plurality of conductive posts 321 arranged around the semiconductor chip SC on the first surface 110A of the redistribution structure 110. Each of the conductive posts 321 may be connected to the wiring structure 113 of the redistribution structure 110. Each of the plurality of conductive posts 321 may include Cu, but is not limited thereto.

Each of the plurality of conductive posts 321 may be connected to the wiring structure 113 of the redistribution structure 110 through one wiring pattern 322 selected from among a plurality of wiring patterns 322 arranged on the first surface 110A of the redistribution structure 110.

Spaces between the semiconductor chip SC and the plurality of conductive posts 321 may be filled with a molding layer 323. In embodiments, the molding layer 323 may include an epoxy-based material, a thermosetting material, a thermoplastic material, or the like. For example, the molding layer 323 may include an epoxy molding compound (EMC). In other embodiments, the molding layer 323 may include an Ajinomoto build-up film (ABF), flame retardant 4 (FR-4), bismaleimide triazine (BT), an EMC, or the like.

An upper redistribution structure 310 may be arranged on the first package structure 320. The upper redistribution structure 310 may include a plurality of upper insulating structures 311 and a plurality of upper wiring structures 313. The plurality of upper insulating structures 311 may cover the plurality of upper wiring structures 313. The plurality of upper wiring structures 313 may pass through one of the plurality of upper insulating structures 311 that are stacked in the vertical direction (Z direction).

The plurality of upper wiring structures 313 may include a plurality of third conductive via patterns 313A, a plurality of third conductive line patterns 313B, a plurality of fourth conductive via patterns 313D, and a plurality of fourth conductive line patterns 313E. Portions of the plurality of third conductive via patterns 313A, the plurality of third conductive line patterns 313B, the plurality of fourth conductive via patterns 313D, and the plurality of fourth conductive line patterns 313E may be connected to each other in the vertical direction. Portions of the plurality of third conductive via patterns 313A, the plurality of third conductive line patterns 313B, the plurality of fourth conductive via patterns 313D, and the plurality of fourth conductive line patterns 313E may be insulated from each other by the plurality of upper insulating structures 311.

According to an embodiment, the upper insulating structure 311 may include a plurality of third insulating layers 311A and a plurality of fourth insulating layers 311B. The plurality of third insulating layers 311A and the plurality of fourth insulating layers 311B may be sequentially stacked on the first package structure 320. FIG. 3 illustrates that three third insulating layers 311A and two fourth insulating layers 311B are sequentially stacked. However, the configurations of the plurality of upper wiring structures 313 and the plurality of upper insulating structures 311 included in the upper redistribution structure 310 are not limited to the illustration of FIG. 3, and various modifications and changes may be made thereto.

The upper insulating structure 311 may include a PID. In embodiments, the upper insulating structure 311 included in the upper redistribution structure 310 may include at least one polymer. For example, the upper insulating structure 311 may include photosensitive polyimide, polybenzoxazole, polyphenol, a benzocyclobutene-based polymer, or a combination thereof. The upper insulating structure 311 may further include a photoactive compound. The photoactive compound may include DNQ or the like, but is not limited thereto.

The third insulating layer 311A may cover at least one of the plurality of third conductive via patterns 313A and the plurality of third conductive line patterns 313B. The third insulating layer 311A that is closest to the first package structure 320 in the vertical direction (Z direction) may cover the plurality of third conductive via patterns 313A.

The fourth insulating layer 311B may be formed between the plurality of third insulating layers 311A. The fourth insulating layer 311B may cover the plurality of fourth conductive via patterns 313D and the plurality of fourth conductive line patterns 313E. In this case, the thicknesses in the vertical direction (Z direction) of the plurality of fourth conductive via patterns 313D and the plurality of fourth conductive line patterns 313E may be identical to the thickness in the vertical direction (Z direction) of the fourth insulating layer 311B. For example, the thickness in the vertical direction (Z direction) of the fourth insulating layer 311B may be in a range of about 2 um to about 5 um.

In addition, the thicknesses in the vertical direction (Z direction) of the second conductive line pattern 113E of the redistribution structure 110 and the fourth conductive line pattern 313E of the upper redistribution structure 310 may be different from each other, but are not limited thereto.

The plurality of fourth conductive line patterns 313E and the plurality of third conductive line patterns 313B may overlap each other in the vertical direction (Z direction). The widths in the horizontal direction (X and Y directions in FIG. 3) of the plurality of fourth conductive line patterns 313E and the plurality of third conductive line patterns 313B may be identical to each other.

The thickness in the vertical direction (Z direction) of the third conductive line pattern 313B and the thickness in the vertical direction (Z direction) of the fourth conductive line pattern 313E may be identical to each other, but are not limited thereto. The thickness in the vertical direction (Z direction) of the third conductive line pattern 313B may be greater than the thickness in the vertical direction (Z direction) of the fourth conductive line pattern 313E, and the thickness in the vertical direction (Z direction) of the third conductive line pattern 313B may be greater than the thickness in the vertical direction (Z direction) of the fourth conductive line pattern 313E.

The fourth insulating layer 311B may be formed between the plurality of third insulating layers 311A, and the plurality of fourth conductive line patterns 313E and the plurality of third conductive line patterns 313B may face each other in the vertical direction (Z direction). Between the third conductive line patterns 313B located at different vertical levels, a plurality of insulating layers, that is, the third and fourth insulating layers 311A and 311B, may be formed in the vertical direction (Z direction). Herein, it is illustrated that the third insulating layer 311A and the fourth insulating layer 311B are formed between the third conductive line patterns 313B in the vertical direction (Z direction). However, embodiments are not limited thereto, and three or more insulating layers may be formed.

The plurality of fourth conductive via patterns 313D may be connected to at least one of the plurality of third conductive line patterns 313B and the plurality of third conductive via patterns 313A. The plurality of fourth conductive via patterns 313D may be located at the same vertical level as the plurality of fourth conductive line patterns 313E in the fourth insulating layer 311B.

As the plurality of fourth conductive line patterns 313E and the plurality of third conductive line patterns 313B overlap each other in the vertical direction (Z direction), the wiring structure 313 of the semiconductor package 300 of inventive concepts may have a thick conductive line pattern.

As the fourth conductive line pattern 313E and the third conductive line pattern 313B overlap each other in the vertical direction (Z direction), the thickness of a conductive line pattern may increase, and thus, the SI and PI characteristics of the semiconductor package 300 may be improved.

In embodiments, the plurality of upper wiring structures 313 may include Cu, Ti, TiW, TiN, Ta, TaN, Cr, Al, In, Mo, Mn, Co, Sn, Ni, Mg, Re, Be, Ga, Ru, or a combination thereof. In particular, the fourth conductive line pattern 313E may include Cu, but is not limited thereto.

A second package structure 380 may be arranged on the upper redistribution structure 310. The second package structure 380 may include a semiconductor chip (not illustrated). A plurality of connection terminals 370 may be arranged between the upper redistribution structure 310 and the second package structure 380. The plurality of connection terminals 370 may be electrically connected to the upper wiring structure 313 of the upper redistribution structure 310. The second package structure 380 may be electrically connected to the semiconductor chip SC and/or the external connection terminal 150 through an electrical path including various combinations of the connection terminal 370, the upper redistribution structure 310, the conductive post 321, the redistribution structure 110, and the conductive pad 130.

In embodiments, the semiconductor chip SC included in the first package structure 320 and the semiconductor chip included in the second package structure 380 may be devices that perform different functions. For example, the semiconductor chip SC may be a logic chip, and the semiconductor chip included in the second package structure 380 may be a memory chip. The logic chip may be a microprocessor. For example, the logic chip may be a CPU, a controller, an ASIC, or the like. The memory chip may be a volatile memory chip, such as DRAM or SRAM, or a non-volatile memory chip, such as PRAM, MRAM, FeRAM, or RRAM. In embodiments, the memory chip may be an HBM DRAM semiconductor chip.

In other embodiments, the semiconductor chip SC included in the first package structure 320 and the semiconductor chip included in the second package structure 380 may be devices that perform the same function or similar functions. For example, at least one of the semiconductor chip SC included in the first package structure 320 and the semiconductor chip included in the second package structure 380 may be an SoC-type AP chip used in a mobile system, for example, a mobile phone, an MP3 player, a navigation device, a PMP, or the like, or a DDR chip used in a mobile system.

In the semiconductor package 300, some conductive pads 130 from among the plurality of conductive pads 130 may be connected to the semiconductor chip SC through the wiring structure 113 included in the redistribution structure 110, and some other conductive pads 130 from among the plurality of conductive pads 130 may be connected to the conductive post 321 through the wiring structure 113 included in the redistribution structure 110. Herein, the conductive pad 130 connected to the semiconductor chip SC through the wiring structure 113 included in the redistribution structure 110, from among the plurality of conductive pads 130, may be referred to as a first conductive pad, and the conductive pad 130 connected to the conductive post 321 through the wiring structure 113 included in the redistribution structure 110, from among the plurality of conductive pads 130, may be referred to as a second conductive pad.

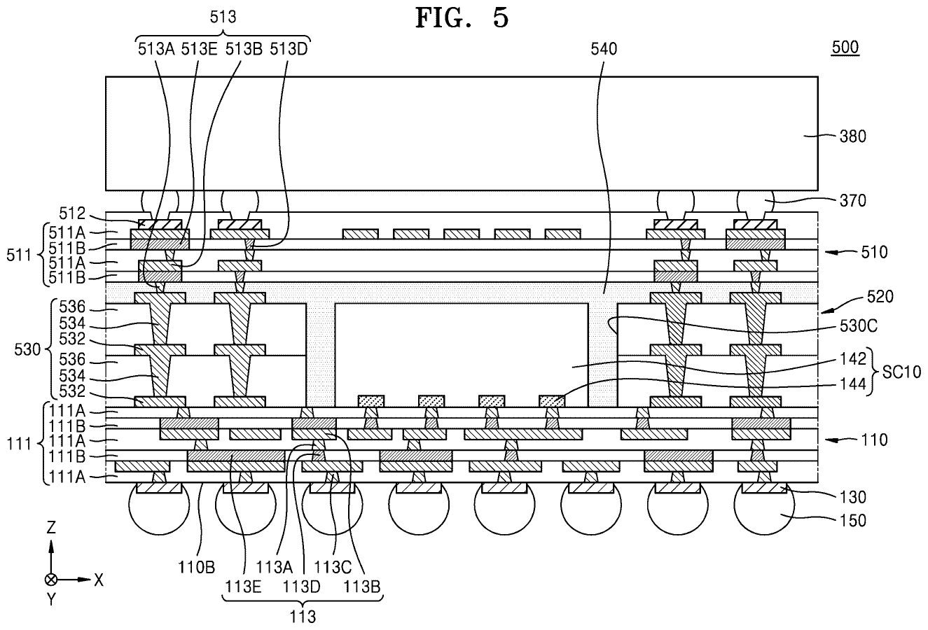

FIG. 5 is a cross-sectional view illustrating a semiconductor package 500 according to another embodiment. In FIG. 5, the same reference numerals as those in FIGS. 1 and 3 refer to the same members, and detailed descriptions thereof are omitted.

Referring to FIG. 5, the semiconductor package 500 may include a first package structure 520 arranged on the redistribution structure 110. The first package structure 520 may have substantially the same configuration as that of the package structure 10 described with reference to FIGS. 1 and 2. However, the first package structure 520 may be a semiconductor package having a fan-out panel-level package (FOPLP) structure. An upper redistribution structure 510 may be arranged on the first package structure 520, and the second package structure 380 may be arranged on the upper redistribution structure 510.

The first package structure 520 may include a frame 530, a semiconductor chip SC10, and a molding layer 540. In embodiments, the semiconductor chip SC10 may have substantially the same configuration as that of the semiconductor chip SC described with reference to FIG. 3. In embodiments, the semiconductor chip SC10 may be a CPU, a microprocessor unit (MPU), a graphics processor unit (GPU), or an AP. In embodiments, the semiconductor chip SC10 may be a controller semiconductor chip for controlling the second package structure 380.

In the first package structure 520, the frame 530 may include a plurality of connection pads 532, a plurality of conductive through vias 534, and a plurality of cores 536. The frame 530 may include a printed circuit board. Each of the plurality of cores 536 may have a structure defining a cavity 530C and include a plate having a quadrangular rim shape when viewed from a plane (an X-Y plane in FIG. 5).

The plurality of connection pads 532, the plurality of conductive through vias 534, and the plurality of cores 536 may form a multi-layer structure. Portions of the plurality of connection pads 532 may be connected to the wiring structure 113 included in the redistribution structure 110. Each of the conductive through vias 534 may pass through one core 536 from among the plurality of cores 536 in the vertical direction (Z direction) and be connected to the connection pad 532.

In embodiments, each of the plurality of cores 536 may include an insulating material in which a phenolic resin, a thermosetting resin such as an epoxy resin, a thermoplastic resin such as polyimide, or at least one resin selected from the aforementioned resins is impregnated into a core material including an inorganic filler and/or glass fibers. For example, each of the plurality of cores 536 may include pre-preg, an ABF, FR-4, tetrafunctional epoxy, polyphenylene ether, BT, epoxy/polyphenylene oxide, thermount, cyanate ester, polyimide, a liquid crystal polymer, or a combination thereof.

In embodiments, each of the plurality of connection pads 532 may include an electrolytically deposited (ED) Cu foil, a rolled-annealed (RA) Cu foil, a stainless steel foil, an Al foil, an ultra-thin Cu foil, sputtered Cu, or a Cu alloy, but is not limited thereto. In embodiments, each of the plurality of conductive through vias 534 may include Cu, Ni, stainless steel, beryllium copper (BeCu), or a combination thereof, but is not limited thereto.

The molding layer 540 may include portions filling spaces between the plurality of cores 536 and the semiconductor chip SC10 in the cavities 530C defined by the plurality of cores 536, and portions covering upper surfaces of the frame 530 and the semiconductor chip SC10. Constituent materials of the molding layer 540 are substantially the same as those of the molding layer 323 described with reference to FIG. 3.

The upper redistribution structure 510 may be arranged on the first package structure 520. The upper redistribution structure 510 may include a plurality of upper insulating structures 511 and a plurality of upper wiring structures 513. The plurality of upper insulating structures 511 may cover the plurality of upper wiring structures 513. The plurality of upper wiring structures 513 may pass through one of the plurality of upper insulating structures 511 that are stacked in the vertical direction (Z direction).

The plurality of upper wiring structures 513 may include a plurality of third conductive via patterns 513A, a plurality of third conductive line patterns 513B, a plurality of fourth conductive via patterns 513D, and a plurality of fourth conductive line patterns 513E. Portions of the plurality of third conductive via patterns 513A, the plurality of third conductive line patterns 513B, the plurality of fourth conductive via patterns 513D, and the plurality of fourth conductive line patterns 513E may be connected to each other in the vertical direction. Portions of the plurality of third conductive via patterns 513A, the plurality of third conductive line patterns 513B, the plurality of fourth conductive via patterns 513D, and the plurality of fourth conductive line patterns 513E may be insulated from each other by the plurality of upper insulating structures 511.

According to an embodiment, the upper insulating structure 511 may include a plurality of third insulating layers 511A and a plurality of fourth insulating layers 511B. The plurality of third insulating layers 511A and the plurality of fourth insulating layers 511B may be sequentially stacked on the first package structure 520. FIG. 5 illustrates that two third insulating layers 511A and two fourth insulating layers 511B are sequentially stacked. However, the configurations of the plurality of upper wiring structures 513 and the plurality of upper insulating structures 511 included in the upper redistribution structure 510 are not limited to the illustration of FIG. 5, and various modifications and changes may be made thereto.

The upper insulating structure 511 may include a PID. In embodiments, the upper insulating structure 511 included in the upper redistribution structure 510 may include at least one polymer. For example, the upper insulating structure 511 may include photosensitive polyimide, polybenzoxazole, polyphenol, a benzocyclobutene-based polymer, or a combination thereof. The upper insulating structure 511 may further include a photoactive compound. The photoactive compound may include DNQ or the like, but is not limited thereto.

The third insulating layer 511A may cover at least one of the plurality of third conductive via patterns 513A and the plurality of third conductive line patterns 513B. The fourth insulating layer 511B may be formed between the plurality of third insulating layers 511A. The fourth insulating layer 511B may cover the plurality of fourth conductive via patterns 513D and the plurality of fourth conductive line patterns 513E. In this case, the thicknesses in the vertical direction (Z direction) of the plurality of fourth conductive via patterns 513D and the plurality of fourth conductive line patterns 513E may be identical to the thickness in the vertical direction (Z direction) of the fourth insulating layer 511B. For example, the thickness in the vertical direction (Z direction) of the fourth insulating layer 511B may be in a range of about 2 um to about 5 um.

In addition, the thicknesses in the vertical direction (Z direction) of the second conductive line pattern 113E of the redistribution structure 110 and the fourth conductive line pattern 513E of the upper redistribution structure 510 may be different from each other, but are not limited thereto.

The plurality of fourth conductive line patterns 513E and the plurality of third conductive line patterns 513B may overlap each other in the vertical direction (Z direction). The widths in the horizontal direction (X and Y directions in FIG. 5) of the plurality of fourth conductive line patterns 513E and the plurality of third conductive line patterns 513B may be identical to each other.

The thickness in the vertical direction (Z direction) of the third conductive line pattern 513B and the thickness in the vertical direction (Z direction) of the fourth conductive line pattern 513E may be identical to each other, but are not limited thereto. The thickness in the vertical direction (Z direction) of the third conductive line pattern 513B may be greater than the thickness in the vertical direction (Z direction) of the fourth conductive line pattern 513E, and the thickness in the vertical direction (Z direction) of the third conductive line pattern 513B may be greater than the thickness in the vertical direction (Z direction) of the fourth conductive line pattern 513E.

The fourth insulating layer 511B may be formed between the plurality of third insulating layers 511A, and the plurality of fourth conductive line patterns 513E and the plurality of third conductive line patterns 513B may face each other in the vertical direction (Z direction). Between the third conductive line patterns 513B located at different vertical levels, a plurality of insulating layers, that is, the third and fourth insulating layers 511A and 511B, may be formed in the vertical direction (Z direction). Herein, it is illustrated that the third insulating layer 511A and the fourth insulating layer 511B are formed between the third conductive line patterns 513B in the vertical direction (Z direction). However, embodiments are not limited thereto, and three or more insulating layers may be formed.

The plurality of fourth conductive via patterns 513D may be connected to at least one of the plurality of third conductive line patterns 513B and the plurality of third conductive via patterns 513A. The plurality of fourth conductive via patterns 513D may be located at the same vertical level as the plurality of fourth conductive line patterns 513E in the fourth insulating layer 511B.

As the plurality of fourth conductive line patterns 513E and the plurality of third conductive line patterns 513B overlap each other in the vertical direction (Z direction), the wiring structure 513 of the semiconductor package 500 of inventive concepts may have a thick conductive line pattern.

As the fourth conductive line pattern 513E and the third conductive line pattern 513B overlap each other in the vertical direction (Z direction), the thickness of a conductive line pattern may increase, and thus, the SI and PI characteristics of the semiconductor package 500 may be improved.

In embodiments, a contact pad 512 may include Ni, Al, or a combination thereof, but is not limited thereto.

The plurality of connection terminals 370 may be arranged between the upper redistribution structure 510 and the second package structure 380. Each of the plurality of connection terminals 370 may be connected to the upper wiring structure 513 through the contact pad 512.

The plurality of connection terminals 370 may be electrically connected to the upper wiring structure 513 of the upper redistribution structure 510. The second package structure 380 may be electrically connected to the semiconductor chip SC10 and/or the external connection terminal 150 through an electrical path including various combinations of the connection terminal 370, the upper redistribution structure 510, the plurality of connection pads 532, the plurality of conductive through vias 534, the redistribution structure 110, and the conductive pad 130.

According to the semiconductor packages 300 and 500 described with reference to FIGS. 3 and 5, similar to the descriptions of the semiconductor package 100 provided with reference to FIGS. 1 and 2, as conductive line patterns included in the redistribution structure 110 and the upper redistribution structures 310 and 510 overlap each other in the vertical direction (Z direction), the thickness of a conductive line patterns may increase, and thus, the SI and PI characteristics of the semiconductor packages 300 and 500 may be improved. Accordingly, the reliability of the semiconductor packages 300 and 500 may be improved.

Hereinafter, a method of manufacturing a semiconductor package according to an embodiment is described in detail with specific examples.

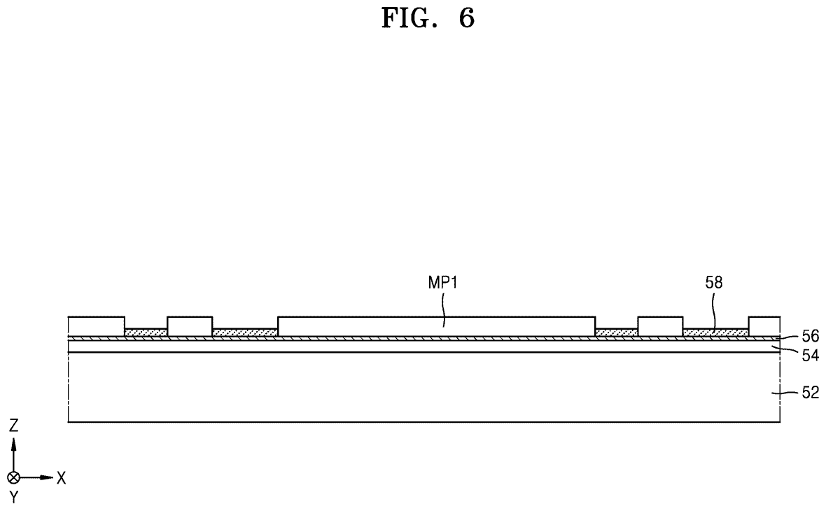

FIGS. 6 to 13 are cross-sectional views sequentially shown according to a manufacturing sequence to explain a method of manufacturing a semiconductor package, according to an embodiment. A method of manufacturing the semiconductor package 300 illustrated in FIG. 3 is described with reference to FIGS. 6 to 13. In FIGS. 6 to 13, the same reference numerals as those in FIGS. 1 to 3 denote the same members, and detailed descriptions thereof are omitted.

Referring to FIG. 6, a tape substrate 52 to which an adhesive layer 54 is attached may be prepared, and a Cu foil 56 may be attached on the adhesive layer 54. Thereafter, a mask pattern MP1 may be formed on the Cu foil 56, and a plurality of wiring patterns 58 may be formed on the Cu foil 56 exposed through the mask pattern MP1.

In embodiments, each of the tape substrate 52 and the adhesive layer 54 may include an organic material. For example, the tape substrate 52 may include polyimide. The mask pattern MP1 may include a photoresist pattern. To form the plurality of wiring patterns 58, an electroplating process using the Cu foil 56 as an electrode may be performed.

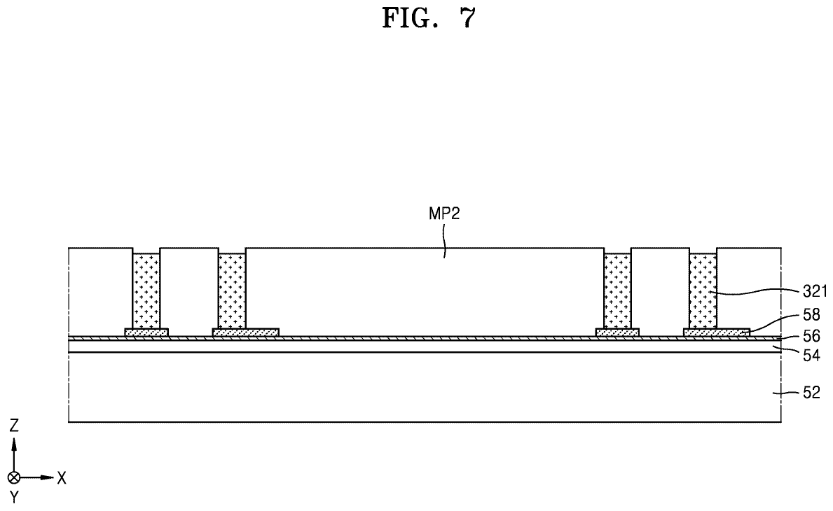

Referring to FIG. 7, the mask pattern MP1 may be removed from the result of FIG. 6, a mask pattern MP2 having openings exposing portions of the plurality of wiring patterns 58 may be formed, and then, a plurality of conductive posts 321 filling the openings may be formed.

In embodiments, the mask pattern MP2 may include a photoresist pattern. To form the plurality of conductive posts 321, an electroplating process using the Cu foil 56 as an electrode may be performed.

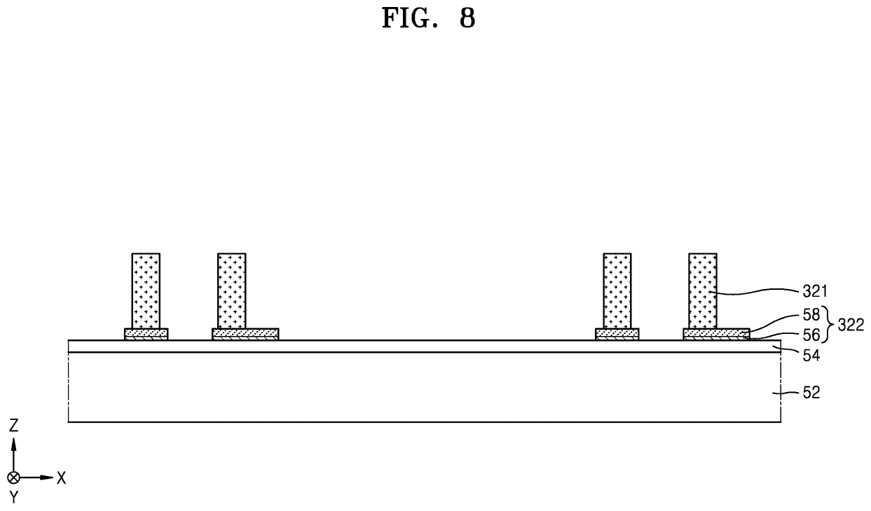

Referring to FIG. 8, the mask pattern MP2 may be removed from the result of FIG. 7, and the Cu foil 56 thus exposed may be etched. As a result, only portions of the Cu foil 56 that are covered by the plurality of wiring patterns 58 may remain on the tape substrate 52. In embodiments, the etching process of the Cu foil 56 may be performed as a wet process, but is not limited thereto. After portions of the Cu foil 56 have been etched, the adhesive layer 54 may be exposed. The stacked structure of the Cu foil 56 remaining on the tape substrate 52 and the wiring pattern 58 may constitute a wiring pattern 322. In the following drawings and descriptions, the stacked structure of the Cu foil 56 and the wiring pattern 58 is illustrated and described as the wiring pattern 322.

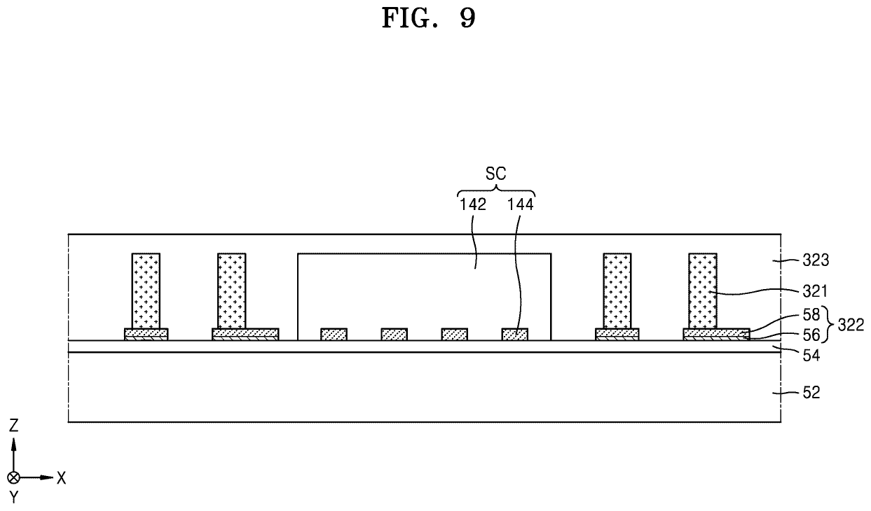

Referring to FIG. 9, a semiconductor chip SC may be attached on the adhesive layer 54 exposed in the result of FIG. 8. An active surface of the semiconductor chip SC, on which a plurality of chip pads 144 are arranged, may face the adhesive layer 54. Thereafter, a molding layer 323 covering the semiconductor chip SC and the plurality of conductive posts 321 may be formed.

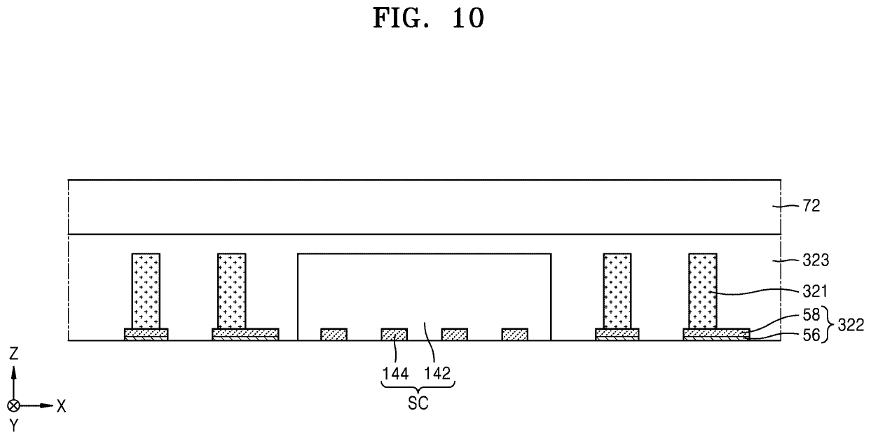

Referring to FIG. 10, a first carrier substrate 72 may be attached on the molding layer 323 in the result of FIG. 9. The first carrier substrate 72 may include any one of a glass substrate, a silicon substrate, and a metal substrate. Thereafter, the adhesive layer 54 and the tape substrate 52 may be removed to expose the Cu foil 56 of the wiring pattern 322 and the plurality of chip pads 144.

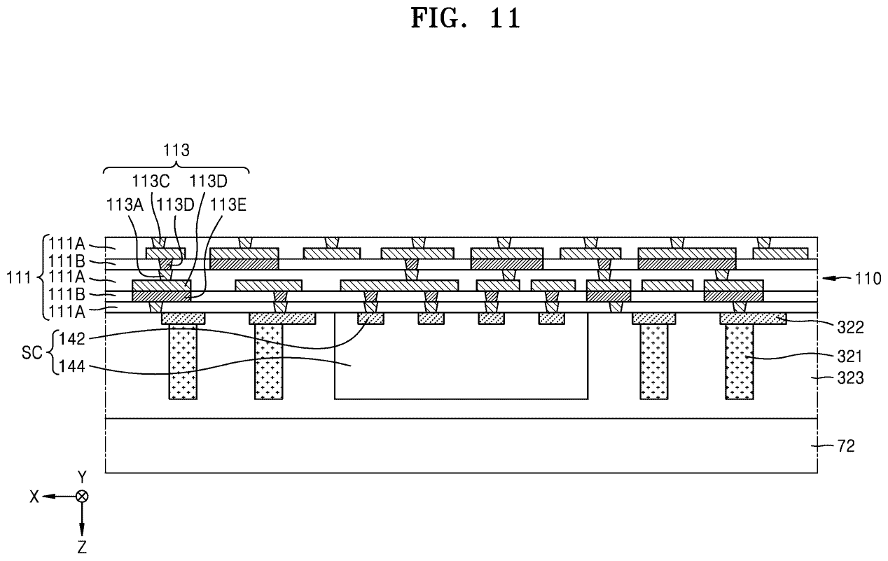

Referring to FIG. 11, in a state in which the result of FIG. 10 is turned over such that the plurality of wiring patterns 322 and the plurality of chip pads 144 face upward in the result of FIG. 10, a redistribution structure 110 may be formed on the plurality of wiring patterns 322 and the plurality of chip pads 144.

To form the redistribution structure 110, a first insulating layer 111A covering the plurality of wiring patterns 322 and the plurality of chip pads 144 may be first formed, a portion of the first insulating layer 111A may be exposed, and then, a plurality of first conductive via patterns 113A may be formed.

A second insulating layer 111B may be formed on the first insulating layer 111A, a portion of the second insulating layer 111B may be exposed, and then, a plurality of second conductive via patterns 113D and a plurality of second conductive line patterns 113E may be formed.

A plurality of first conductive line patterns 113B may be formed on the second insulating layer 111B. In this case, the plurality of first conductive line patterns 113B may overlap the plurality of second conductive line patterns 113E in a vertical direction (Z direction). Lower surfaces of the plurality of first conductive line patterns 113B may face upper surfaces of the plurality of second conductive line patterns 113E. The widths in a horizontal direction (X and Y directions in FIG. 11) of the plurality of second conductive line patterns 113E and the plurality of first conductive line patterns 113B may be identical to each other. A first insulating layer 111A covering the plurality of first conductive line patterns 113B may be formed, a portion of the first insulating layer 111A may be exposed, and then, a plurality of first conductive via patterns 113A may be formed.

Repeatedly, a second insulating layer 111B and a first insulating layer 111A may be stacked, and a plurality of first conductive via patterns 113A, a plurality of first conductive line patterns 113B, and a plurality of second conductive via patterns 113D, and a plurality of second conductive line patterns 113E may be formed, to thereby form the redistribution structure 110. In addition, processes of forming an outermost wiring pattern 113C constituting another portion of the wiring structure 113 may be performed on the plurality of first conductive line patterns 113B formed on the uppermost first insulating layer 111A.

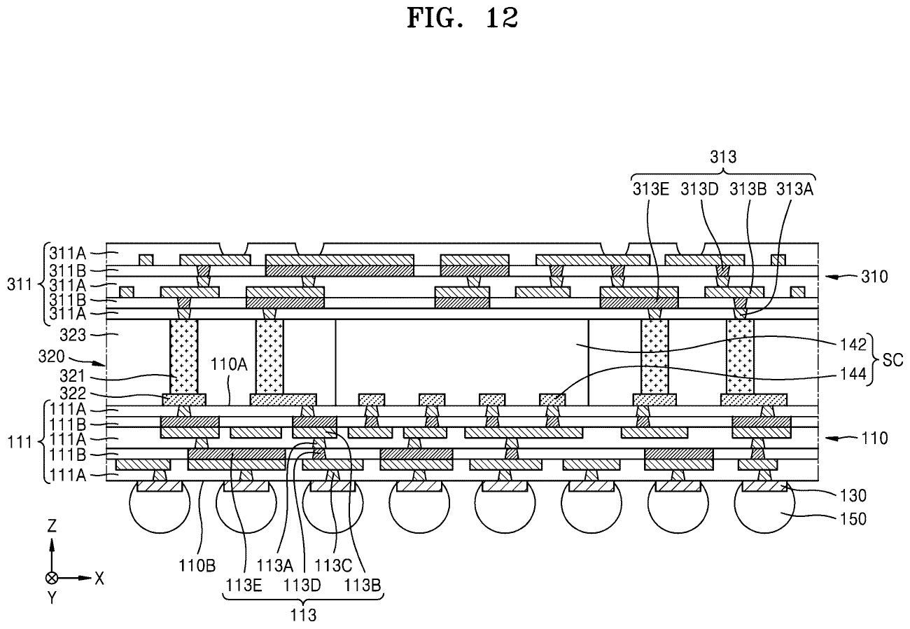

Referring to FIG. 12, in the result of FIG. 11, a second carrier substrate may be attached on the redistribution structure 110 by using an adhesive layer. The second carrier substrate may include a glass substrate, a silicon substrate, a metal substrate, or a combination thereof.

Thereafter, the first carrier substrate 72 (see FIG. 11) may be removed, and an exposed surface of the molding layer 323 may be planarized to expose upper surfaces of the plurality of conductive posts 321. Thereafter, an upper redistribution structure 310 may be formed on the semiconductor chip SC, the plurality of conductive posts 321, and the molding layer 323. To form the upper redistribution structure 310, processes similar to those described in the formation of the redistribution structure 110 with reference to FIG. 11 may be performed.

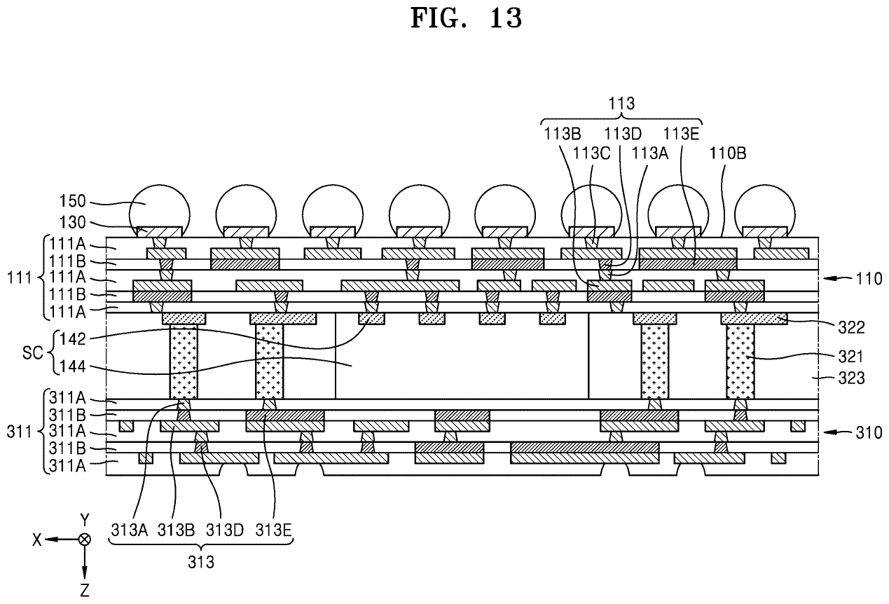

Referring to FIG. 13, in the result of FIG. 12, the second carrier substrate and the adhesive layer may be removed to expose an insulating structure 111 and a plurality of outermost wiring patterns 113C of the redistribution structure 110. After forming a plurality of conductive pads 130, a plurality of external connection terminals 150 may be formed on the plurality of conductive pads 130.

Thereafter, as illustrated in FIG. 3, in the result of FIG. 13, a plurality of connection terminals 370 may be formed on the upper redistribution structure 310, and a second package structure 380 may be attached on the plurality of connection terminals 370, to thereby form the semiconductor package 300.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor package comprising:
a redistribution structure including a wiring structure and an insulating structure covering the wiring structure; and
a package structure on the redistribution structure, the package structure including a semiconductor chip connected to the wiring structure, wherein
the insulating structure of the redistribution structure includes a plurality of first insulating layers and a second insulating layer between the plurality of first insulating layers,
the plurality of first insulating layers include at least one of a first conductive line pattern and a first conductive via pattern, and
the second insulating layer includes a second conductive line pattern overlapping the first conductive line pattern in a vertical direction.

2. The semiconductor package of claim 1, wherein
the plurality of first insulating layers include the first conductive line pattern,
a width in a horizontal direction of the second conductive line pattern is identical to a width in the horizontal direction of the first conductive line pattern, and
the first conductive line pattern faces the second conductive line pattern in the vertical direction.

3. The semiconductor package of claim 1, wherein the second conductive line pattern comprises copper.

4. The semiconductor package of claim 1, wherein
a thickness in the vertical direction of an insulating structure in the second insulating layer and a thickness of the second conductive line pattern in the vertical direction are identical to each other.

5. The semiconductor package of claim 4, wherein the thickness in the vertical direction of the insulating structure in the second insulating layer is 2 um to 5 um.

6. The semiconductor package of claim 1, wherein
the second insulating layer further comprises a second conductive via pattern connected to at least one of the first conductive line pattern and the first conductive via pattern.

7. The semiconductor package of claim 6, wherein
the second conductive line pattern and the second conductive via pattern are located at a same vertical level in the second insulating layer.

8. The semiconductor package of claim 1, wherein the plurality of first insulating layers and the second insulating layer comprise a photoimageable dielectric (PID).

9. The semiconductor package of claim 1, further comprising:
a conductive pad connected to the wiring structure; and
an external connection terminal on the conductive pad.

10. A semiconductor package comprising:
a package structure including a semiconductor chip;
a first redistribution structure facing a first surface of the package structure in a vertical direction, the first redistribution structure including a first wiring structure and a first insulating structure covering the first wiring structure; and
a second redistribution structure facing a second surface of the package structure in the vertical direction, the second redistribution structure including a second wiring structure and a second insulating structure covering the second wiring structure, the second surface of the package structure being opposite to the first surface of the package structure, wherein
the first insulating structure includes a plurality of first insulating layers and a second insulating layer between the plurality of first insulating layers,
the plurality of first insulating layers include at least one of a first conductive line pattern and a first conductive via pattern,
the second insulating layer includes a second conductive line pattern overlapping the first conductive line pattern in the vertical direction,
the second insulating structure includes a plurality of third insulating layers and a fourth insulating layer between the plurality of third insulating layers,
the plurality of third insulating layers include at least one of a third conductive line pattern and a third conductive via pattern, the fourth insulating layer includes a fourth conductive line pattern overlapping the third conductive line pattern in the vertical direction.

11. The semiconductor package of claim 10, wherein
a width in a horizontal direction of the second conductive line pattern is identical to a width in the horizontal direction of the first conductive line pattern,
the first conductive line pattern faces the second conductive line pattern in the vertical direction,
a width in the horizontal direction of the third conductive line pattern is identical to a width in the horizontal direction of the fourth conductive line pattern, and
the fourth conductive line pattern faces the third conductive line pattern in the vertical direction.

12. The semiconductor package of claim 10, wherein the second conductive line pattern and the fourth conductive line pattern comprise copper.

13. The semiconductor package of claim 10, wherein a thickness of the second conductive line pattern in the vertical direction is different from a thickness of the fourth conductive line pattern in the vertical direction.

14. The semiconductor package of claim 10, wherein
the second insulating layer further comprises a second conductive via pattern connected to at least one of the first conductive line pattern and the first conductive via pattern, and
the fourth insulating layer further comprises a fourth conductive via pattern connected to at least one of the third conductive line pattern and the third conductive via pattern.

15. The semiconductor package of claim 14, wherein
the second conductive line pattern and the second conductive via pattern are located at a same vertical level in the second insulating layer, and
the fourth conductive line pattern and the fourth conductive via pattern are located at a same vertical level in the fourth insulating layer.

16. The semiconductor package of claim 10, wherein the plurality of first insulating layers, the second insulating layer, the plurality of third insulating layers, and the fourth insulating layer comprise a photoimageable dielectric (PID).

17. A method of manufacturing a semiconductor package, the method comprising:
forming a package structure including a semiconductor chip; and
forming a redistribution structure on the package structure, wherein
the forming the redistribution structure includes
forming a first conductive via pattern and a first insulating layer on the package structure, the first insulating layer covering the first conductive via pattern,
forming a second conductive line pattern, a second conductive via pattern, and a second insulating layer on the first insulating layer, the second insulating layer covering the second conductive line pattern and the second conductive via pattern, and
forming a first conductive line pattern and a third insulating layer on the second insulating layer, the third insulating layer covering the first conductive line pattern, the first conductive line pattern facing the second conductive line pattern in a vertical direction.

18. The method of claim 17, wherein
the forming the second conductive line pattern, the second conductive via pattern, and the second insulating layer on the first insulating layer comprises forming the second insulating layer on the first insulating layer and then exposing the second insulating layer to form the second conductive line pattern and the second conductive via pattern.

19. The method of claim 18, wherein
the second insulating layer, the second conductive line pattern, and the second conductive via pattern are formed to have identical thicknesses in the vertical direction.

20. The method of claim 17, wherein
a width in a horizontal direction of the second conductive line pattern is identical to a width in the horizontal direction of the first conductive line pattern, and
the first conductive line pattern faces the second conductive line pattern in the vertical direction.
